(19) United States
(12) Patent Application Publication
(10) Pub. No.: US 2014/0185203 A1
(43) Pub. Date: Jul. 3, 2014

(54) ELECTRONIC DEVICE WITH BATTERY

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: LEI LIU, Shenzhen (CN); GUO-YI CHEN, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/140,306

(22) Filed: Dec. 24, 2013

(30) Foreign Application Priority Data
Dec. 29, 2012 (CN) 2012105884917

(51) Int. Cl. H05K 7/00

(52) U.S. Cl. CPC H05K 7/00
USPC 361/679.01

(57) ABSTRACT

An electronic device includes a first battery and a second battery. The first battery defines a receiving portion for receiving the second battery, to charge the second battery.

### BACKGROUND

1. Technical Field

The present disclosure relates to an electronic device comprising a battery.

2. Description of Related Art

A portable device, such as a mobile phone, may need to be charged by connecting the mobile phone to an external power source, such as a wall socket or a computer, by a cable. However, it is inconvenient to carry the wire with the mobile phone.

Therefore, there is room for improvement in the art.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is an isometric view of an embodiment of an electronic device, wherein the electronic device includes first and second batteries.

FIG. 2 is an isometric view of the first battery with the second battery of FIG. 1.

FIG. 3 is a block diagram of the first battery of FIG. 1.

FIG. 4 is an enlarged, side plan view of a receiving portion of the first battery of FIG. 1.

FIG. 5 is an isometric view of the second battery of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

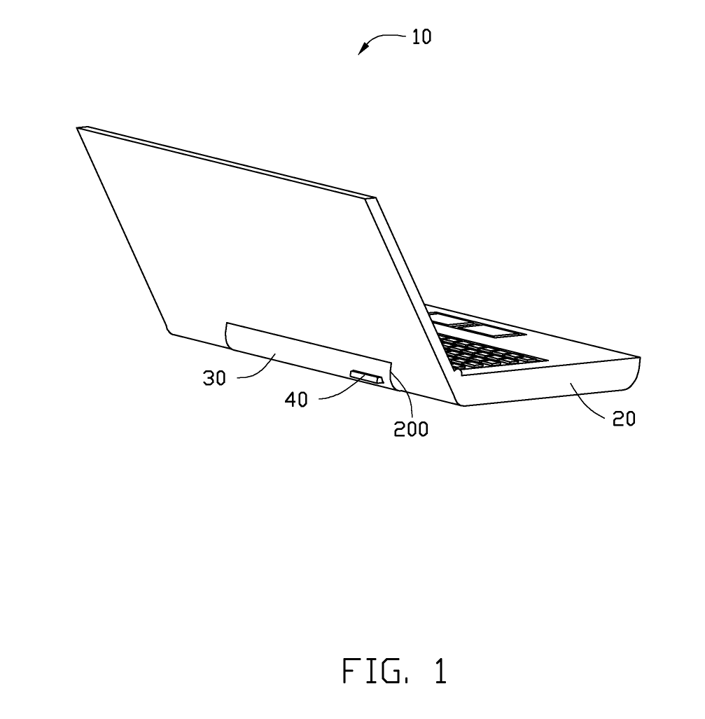

FIG. 1 illustrates an embodiment of an electronic device 10. The electronic device 10 comprises a main body 20, a first battery 30, and a second battery 40. A rear side of the main body 10 defines a first receiving portion 200 to receive the first battery 30. The first battery 30 provides power for the electronic device 10 when received in the first receiving portion 200. In the illustrated embodiment, the electronic device 10 is a notebook computer.

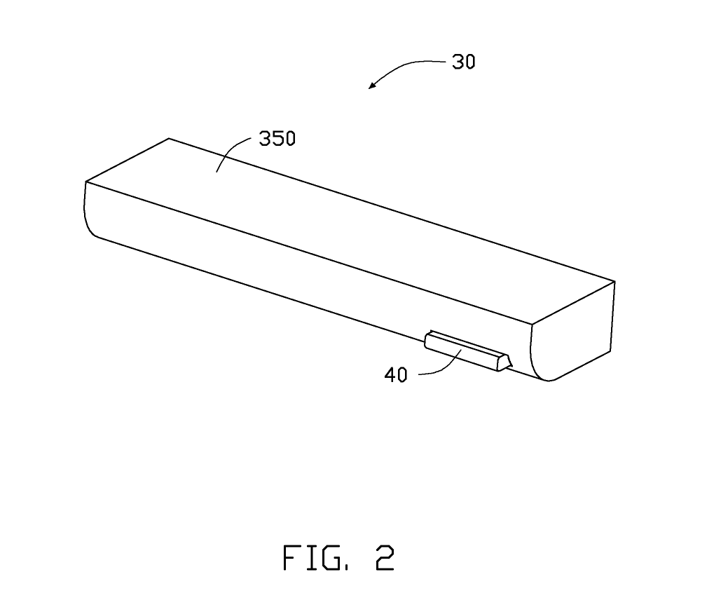

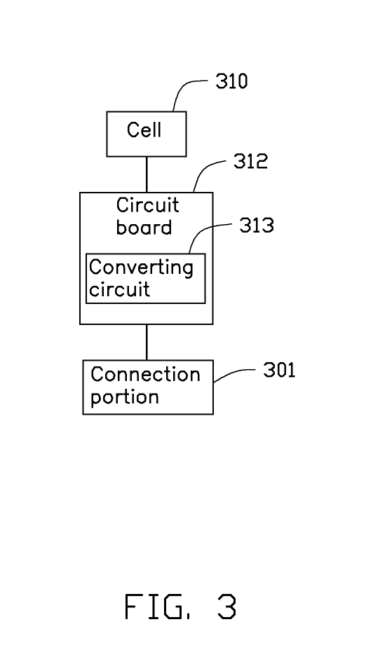

FIGS. 2 and 3 show that the first battery 30 comprises a shell 350, a plurality of cells 310 (only one shown), and a circuit board 312. The cells 310 and the circuit board 312 are received in the shell 350. The cells 310 are configured to store electrical power. The circuit board 312 comprises a converting circuit 313 to convert a power provided by the cells 310 into a power suitable for charging the second battery 40 by adjusting a voltage provided to the second battery 40. Thus, the cells 310 are controlled to either power the electronic device 10 or charge the second battery 40.

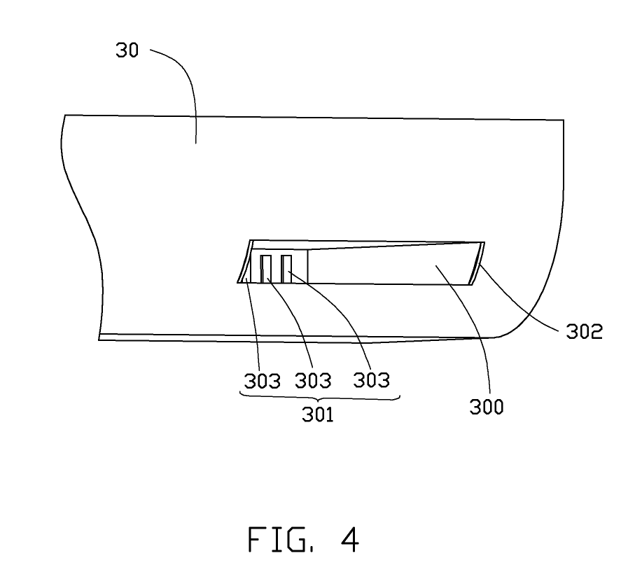

FIG. 4 illustrates that a rear side of the shell 350 defines a second receiving portion 300 for receiving the second battery 40. A connection portion 301 is formed on a back wall of the second receiving portion 300, and each of two elastic positioning portions 302 protrudes from a corresponding sidewall of the second receiving portion 300.

The connection portion 301 comprises a plurality of conductive pieces 303 electrically connected to the converting circuit 313 to receive the voltage provided by the converting circuit 313.

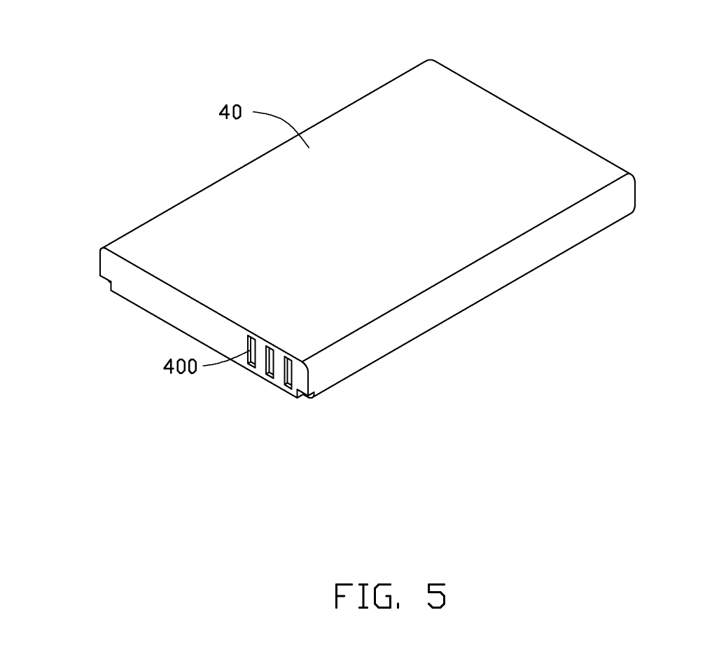

FIG. 5 illustrates that the second battery 40 forms a plurality of metal pieces 400 to be connected to the conductive pieces 303. In one embodiment, the second battery 40 is suitable for a mobile phone.

When the second battery 40 is received in the second receiving portion 300, the metal pieces 400 are connected to the conductive pieces 303, and the positioning portions 302 resist against sides of the second battery 40 to hold the second battery 40 in position for charging. The converting circuit 313 converts a voltage of the first battery 30 into a voltage suitable for charging the second battery 40.

While the disclosure has been described by way of example and in terms of a preferred embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. An electronic device, comprising:
a first battery providing power for the device, comprising:
a shell defining a receiving portion, wherein a connection portion is formed on an inner wall of the receiving portion;
a plurality of cells located in the shell; and
a circuit board located in the shell and comprising a converting circuit connected to the connection portion, wherein the circuit board regulates power provided by the plurality of cells; and
a second battery comprising a plurality of metal pieces, wherein when the second battery is placed in the receiving portion, the plurality of metal pieces is connected to the connection portion.

2. The electronic device of claim 1, wherein at least one positioning portion is formed on the inner wall of the receiving portion, to fix the second battery within the receiving portion.

3. The electronic device of claim 2, wherein the connection portion comprises a plurality of conductive pieces, when the second battery is placed in the receiving portion, and the plurality of metal pieces of the second battery are connected to the plurality of conductive pieces.

4. The electronic device of claim 1, wherein the first battery is suitable for a notebook computer.

5. The electronic device of claim 1, wherein the second battery is suitable for a mobile phone.
